(19) United States
(12) Patent Application Publication
(10) Pub. No.: US 2017/0338239 A1
(43) Pub. Date: Nov. 23, 2017

(54) SEMICONDUCTOR STRUCTURE AND METHOD FOR MANUFACTURING THE SAME

(71) Applicant: UNITED MICROELECTRONICS CORP., Hsinchu (TW)

(72) Inventors: Wei-Chang Liu, Singapore (SG); Zhen Chen, Singapore (SG); Shen-De Wang, Zhudong Township (TW); Wei Ta, Singapore (SG); Wang Xiang, Singapore (SG); Yi-Shan Chiu, Taoyuan (TW)

(21) Appl. No.: 15/161,419

(22) Filed: May 23, 2016

(51) Int. Cl. H01L 27/11582; H01L 29/66

(52) U.S. Cl. CPC H01L 27/11582; H01L 29/66833

(57) ABSTRACT

A semiconductor structure includes a substrate and a plurality of memory cells disposed on the substrate. Each memory cell includes a gate structure. The gate structures are spaced from each other by a spacing S. Each gate structure includes a dielectric layer and a gate electrode. The dielectric layer has an U-shape and defines an opening toward upside. The gate electrode is disposed in the opening. Each gate structure has a length L. A ratio of S/L is smaller than 1.

### BACKGROUND

### Technical Field

The disclosure relates to a semiconductor structure and a method for manufacturing the same. More particularly, the disclosure relates to a semiconductor structure comprising memory cells and a method for manufacturing the same.

### Description of the Related Art

Memory devices have been widely used in electronic systems for data storage. They can be divided into two categories: volatile memory device and non-volatile memory device. A volatile memory device requires power to maintain the stored information. In contrast, a non-volatile memory device retains its information even when power is turned off. The flash memory device is a main category of the non-volatile memory device. The flash memory devices comprise NOR flash memory devices and NAND flash memory devices. Compared to a NOR flash memory device, a NAND flash memory device requires less chip area and thereby reduces the cost. In other words, the NAND flash memory devices meet the current direction of the development of semiconductor devices that reduces the sizes and the costs thereof.

### SUMMARY

This disclosure is directed to a semiconductor structure and a method for manufacturing the same. The semiconductor structure comprises memory cells, which can particularly, but not limited to, constitute a NAND flash memory structure. According to embodiments described herein, the size of a cell area of the semiconductor structure can be further reduced.

According to some embodiments, a semiconductor structure comprises a substrate and a plurality of memory cells disposed on the substrate. Each of the memory cells comprises a gate structure. The gate structures are spaced from each other by a spacing S. Each of the gate structures comprises a dielectric layer and a gate electrode. The dielectric layer has an U-shape and defines an opening toward upside. The gate electrode is disposed in the opening. Each of the gate structures has a length L. A ratio of S/L is smaller than 1.

According to some embodiments, a method for manufacturing a semiconductor structure comprises the following steps. First, a plurality of hard mask features are formed on a substrate by sidewall image transfer (SIT) technique. The hard mask features are spaced from each other. Then, a dielectric layer is formed conformally covering the hard mask features. The dielectric layer defines a plurality of open spaces. A conductive material is filled into the open spaces. Thereafter, the hard mask features and portions of the dielectric layer formed thereon are removed, so as to form a plurality of gate structures respectively for a plurality of memory cells. The gate structures are spaced from each other by a spacing S. For each of the gate structures, the dielectric layer has an U-shape and defines an opening toward upside, the conductive material constitute a gate electrode disposed in the opening, the gate structure has a length L, and a ratio of S/L is smaller than 1.

### BRIEF DESCRIPTION OF THE DRAWINGS

FIGS. 1A to 1M illustrate a semiconductor structure at various stages of manufacturing according to embodiments.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. For clarity, the elements in the figures may not reflect their real sizes. Further, it is contemplated that elements and features of one embodiment may be beneficially incorporated in another embodiment without further recitation.

Now the description is directed to a method for manufacturing a semiconductor structure. First, a plurality of hard mask features spaced from each other are formed on a substrate. This can be achieved, for example, by sidewall image transfer (SIT) technique.

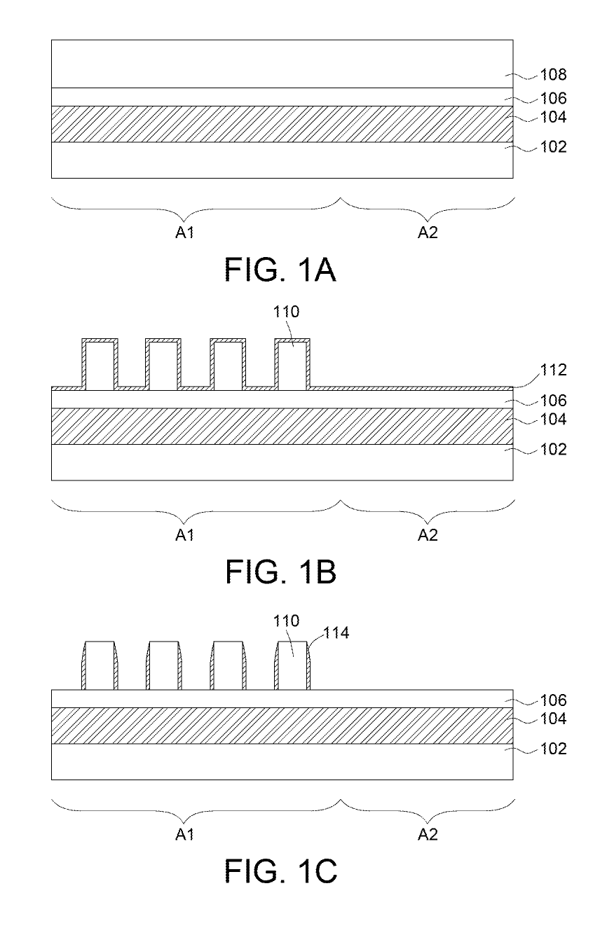

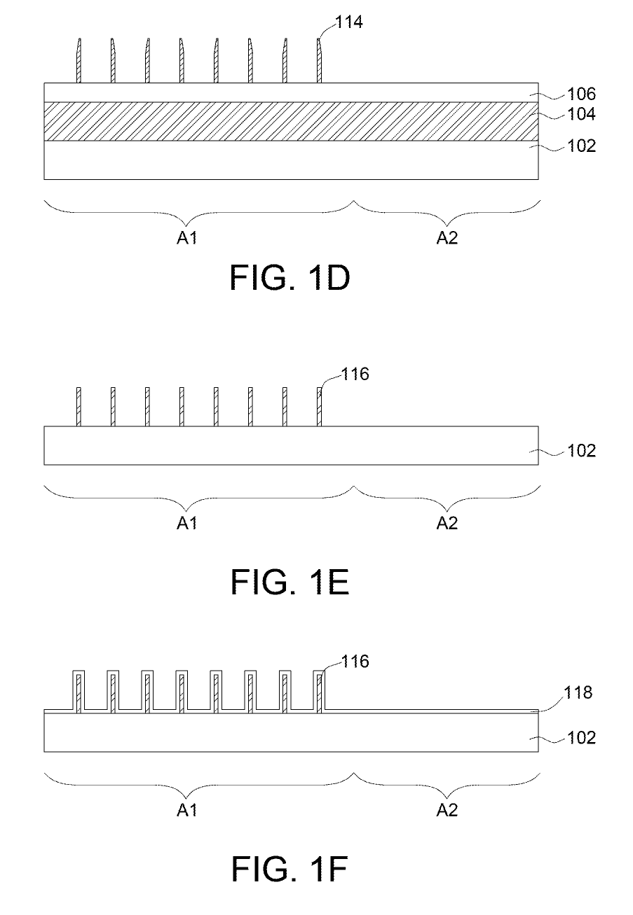

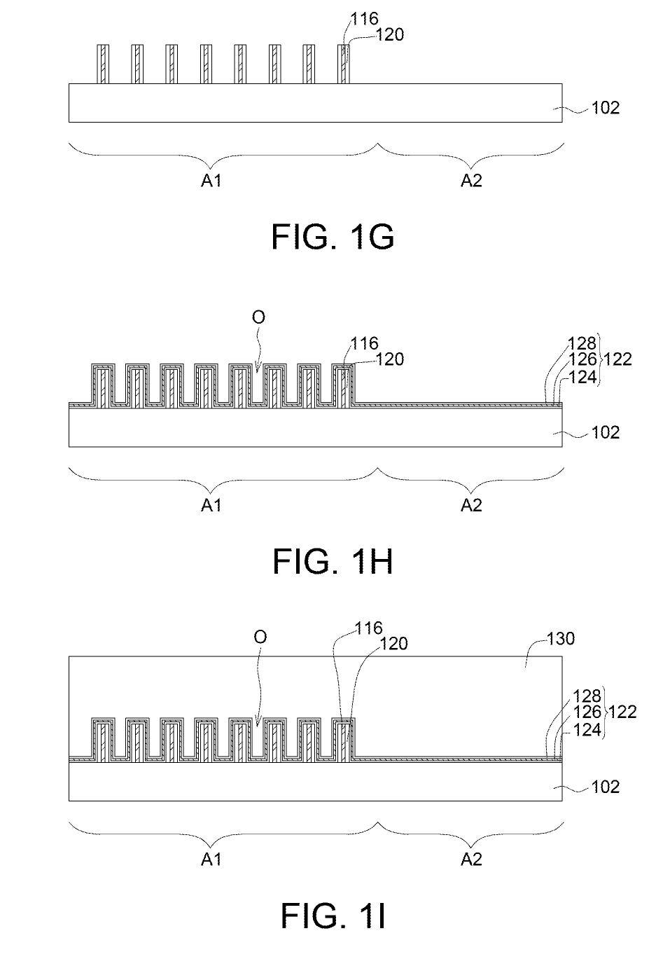

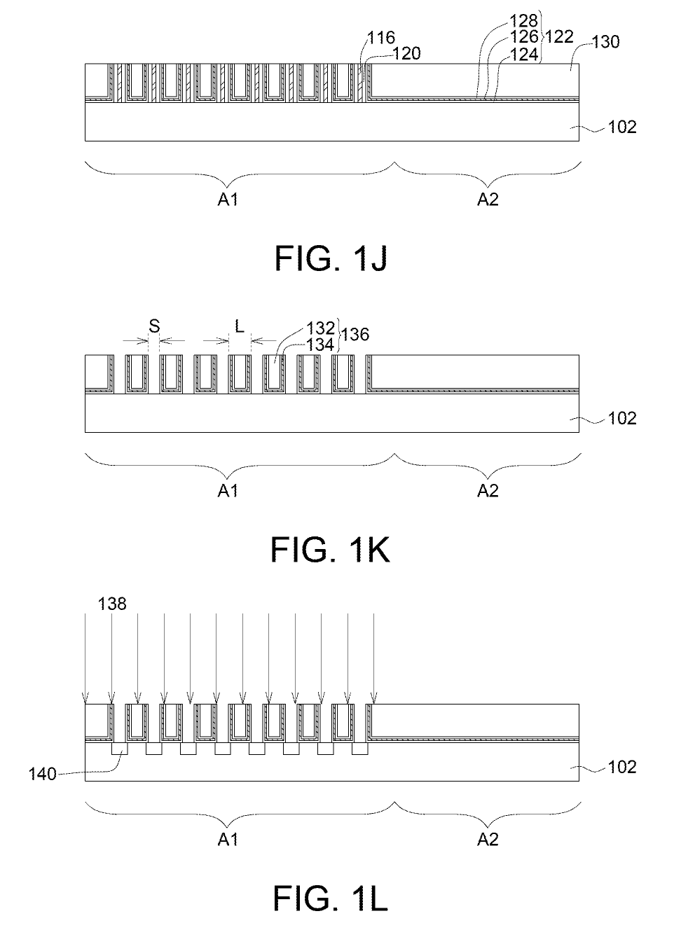

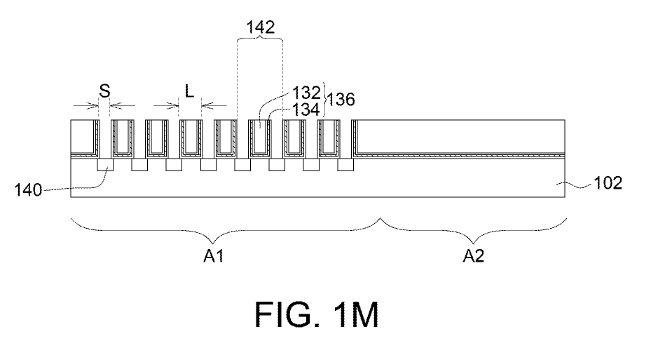

Referring to FIG. 1A, a substrate 102 is provided. A cell area A1 and a logic area A2 may be defined on the substrate 102. A hard mask layer 104 is formed on the substrate 102. The hard mask layer 104 may be formed of SiN. The hard mask layer 104 may have a thickness of about 40 nm. An intermediate layer 106 is formed on the hard mask layer 104. The intermediate layer 106 may be formed of undoped silicon glass (USG). The intermediate layer 106 may have a thickness of about 30 nm. A place holder layer 108 is formed on the intermediate layer 106. The place holder layer 108 may be formed of silicon. According to some embodiments, one or more addition layers may also be formed. For example, a layer of organic dielectric material and silicon (not shown) for a lithography process may be formed on the place holder layer 108. The formation of the layers described above and in the following paragraphs may be conducted, for example, by deposition.

The place holder layer 108 is patterned. As such, a plurality of place holders 110 are formed on the intermediate layer 106 in the cell area A1, as shown in FIG. 1B. A spacer layer 112 is formed conformally covering the place holders 110. The spacer layer 112 may be formed of SiN. The spacer layer 112 may have a thickness of about 20 nm.

Then, the place holders 110 and portions of the spacer layer 112 formed thereon are removed, so as to form a plurality of spacers 114 on the intermediate layer 106. For example, portions of the spacer layer 112 formed on the place holders 110 and the intermediate layer 106 may be firstly removed such as by etching, as shown in FIG. 1C. Then, the place holders 110 can be removed, as shown in FIG. 1D.

Thereafter, a pattern of the spacers 114 can be transferred to the hard mask layer 104, as shown in FIG. 1E. As such, a plurality of hard mask features 116 are formed on the substrate 102 by SIT technique, wherein the hard mask features 116 are spaced from each other.

Optionally, in some embodiments, liners beneficial for the protection of a dielectric layer formed in the following steps (such as the dielectric layer 122 shown in FIG. 1H) from damage in an etching step may be formed. Referring to FIG. 1F, a liner layer 118 may be formed conformally covering the hard mask features 116. The liner layer 118 may be formed of high temperature oxide (HTO). The liner layer 118 may have a thickness of about 50 Å. Then, the redundant portions of the liner layer 118 is removed, so as to form liners 120 on sidewalls of the hard mask features 116, as shown in FIG. 1G. The liners 120 on the sidewalls of the hard mask features 116 may have a thickness of about 30 Å.

Referring to FIG. 1H, thereafter, a dielectric layer 122 is formed conformally covering the hard mask features 116. The dielectric layer 122 defines a plurality of open spaces 0. According to some embodiments, the dielectric layer 122 may be a memory layer. For example, as shown in FIG. 1H, the dielectric layer 122 comprises an oxide layer 124, a nitride layer 126 and an oxide layer 128 constituting an ONO structure. Alternatively, the dielectric layer 122 may have an ONONO structure or another suitable structure for a memory layer.

Referring to FIG. 1I, a conductive material 130 is filled into the open spaces 0. The conductive material 130 may be polysilicon or another suitable material for a gate electrode. In some embodiments, as shown in FIG. 1L, the conductive material 130 may be overfilled and cover the whole structure. Then, the redundant conductive material 130 is removed, for example, by a planarization step, as shown in FIG. 1J. The planarization step may be a chemical mechanical planarization (CMP) step. Through the planarization step, portions of the dielectric layer 122 formed on the hard mask features 116 are removed, and the hard mask features 116 are exposed for the following etching step.

Referring to FIG. 1K, the hard mask features 116 is removed, for example, by an etching step. The liners 120, if exist, are also removed at the etching step. The etching step may use H₃PO₄ as an etchant. After the hard mask features 116 and portions of the dielectric layer 122 formed thereon have been removed, a plurality of gate structures 136 respectively for a plurality of memory cells (such as the memory cells 142 shown in FIG. 1M) are formed. The gate structures 136 are spaced from each other by a spacing S. The spacing S can be smaller than 20 nm, such as about 10 nm to about 20 nm. For each of the gate structures 136, the dielectric layer 134 (i.e., the portion of the dielectric layer 122 belong to the gate structure 136) has an U-shape and defines an opening toward upside, and the conductive material 130 constitute a gate electrode 132 disposed in the opening. Further, each gate structure 136 has a length L. The length L may be about 30 nm to about 50 nm. A ratio of S/L is smaller than 1. In some embodiments, the ratio of S/L substantially equals to 1/2. For example, the length L may be about 40 nm, and the spacing S may be about 20 nm.

Thereafter, doped regions 140 may be formed in the substrate 102 between the gate structures 136, as shown in FIG. 1L. The implant may be N+ implant or P+ implant. In particular, the implant may be N+ implant for NAND flash cells.

Now referring to FIG. 1M, a semiconductor structure manufactured by a method according to embodiments described above is shown. The semiconductor structure comprises a substrate 102 and a plurality of memory cells 142 disposed on the substrate 102. Each of the memory cells 142 comprises a gate structure 136. The gate structures 136 are spaced from each other by a spacing S. Each of the gate structures 136 comprises a dielectric layer 134 and a gate electrode 132. The dielectric layer 134 has an U-shape and defines an opening toward upside. The dielectric layer 134 may be a memory layer. For example, the dielectric layer 134 may have an ONO or ONONO structure. The gate electrode 132 is disposed in the opening. Each of the gate structures 136 has a length L. A ratio of S/L is smaller than 1. For example, the ratio of S/L substantially equals to 1/2. Each of the memory cells 142 may further comprise two doped regions 140 disposed in the substrate 102 at two sides of the gate electrode 132, respectively. The memory cells 142 may be NAND flash cells. In some embodiments, as shown in FIG. 1M, the memory cells 142 constitute a string.

So far it is hard to manufacture NAND flash cells with a spacing S of gate structures less than 40 nm due to the limit of lithography. However, through the method for manufacturing a semiconductor structure described herein, the memory cells in the semiconductor structure can have a spacing equal to or even less than 20 nm. As such, the size of a cell area of the semiconductor structure can be further reduced.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A semiconductor structure, comprising:
a substrate; and
a plurality of memory cells disposed on the substrate, each of the memory cells comprising a gate structure, wherein the gate structures are spaced from each other by a spacing S, and each of the gate structures comprising:
a dielectric layer having an U-shape and defining an opening toward upside; and
a gate electrode disposed in the opening;
wherein each of the gate structures has a length L, and a ratio of S/L is smaller than 1, and wherein the spacing S is smaller than 20 nm.

2. The semiconductor structure according to claim 1, wherein the memory cells are NAND flash cells.

3. The semiconductor structure according to claim 1, wherein the memory cells constitute a string.

4. The semiconductor structure according to claim 1, wherein the dielectric layer is a memory layer.

5. The semiconductor structure according to claim 1, wherein the dielectric layer has an ONO or ONONO structure.

6. The semiconductor structure according to claim 1, wherein the ratio of S/L substantially equals to 1/2.

7. The semiconductor structure according to claim 1, wherein each of the memory cells further comprises two doped regions disposed in the substrate at two sides of the gate electrode, respectively.

8. A method for manufacturing a semiconductor structure, comprising:
forming a plurality of hard mask features on a substrate by sidewall image transfer (SIT) technique, the hard mask features spaced from each other;
forming a dielectric layer conformally covering the hard mask features, the dielectric layer defining a plurality of open spaces;
filling a conductive material into the open spaces;
removing the hard mask features and portions of the dielectric layer formed thereon, so as to form a plurality of gate structures respectively for a plurality of memory cells, wherein the gate structures are spaced from each other by a spacing S, and for each of the gate structures, the dielectric layer has an U-shape and defines an opening toward upside, the conductive material constitute a gate electrode disposed in the opening, the gate structure has a length L, and a ratio of S/L is smaller than 1.

9. The method according to claim 8, wherein forming the hard mask features comprises:
forming a hard mask layer on the substrate;
forming an intermediate layer on the hard mask layer;
forming a plurality of place holders on the intermediate layer;
forming a spacer layer conformally covering the place holders;
removing the place holders and portions of the spacer layer formed thereon, so as to form a plurality of spacers on the intermediate layer; and
transferring a pattern of the spacers to the hard mask layer.

10. The method according to claim 9, wherein the hard mask layer is formed of SiN.

11. The method according to claim 8, further comprising:
before forming the dielectric layer, forming liners on sidewalls of the hard mask features;
wherein the liners are removed at a same step of removing the hard mask features.

12. The method according to claim 8, wherein removing the hard mask features and the portions of the dielectric layer formed thereon comprises a planarization step and an etching step.

13. The method according to claim 12, wherein the etching step using H₃PO₄ as an etchant.

14. The method according to claim 8, wherein the memory cells are NAND flash cells.

15. The method according to claim 8, wherein the memory cells constitute a string.

16. The method according to claim 8, wherein the dielectric layer is a memory layer.

17. The method according to claim 8, wherein the dielectric layer has an ONO or ONONO structure.

18. The method according to claim 8, wherein the ratio of S/L substantially equals to 1/2.

19. The method according to claim 8, further comprising:
forming doped regions in the substrate between the gate structures.
